(19) United States
(12) Patent Application Publication
(10) Pub. No.: US 2007/0082427 A1
(43) Pub. Date: Apr. 12, 2007

(54) Method for manufacturing a compound semiconductor device having an improved via hole

(75) Inventors: Takeo Shirahama, Tokyo (JP); Shinichi Miyakuni, Tokyo (JP); Toshiaki Kitano, Tokyo (JP); Takahiro Iino, Hyogo (JP); Kouichirou Nishizawa, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Electric Corporation, Tokyo (JP)

(21) Appl. No.: 11/472,324

(22) Filed: Jun. 22, 2006

(30) Foreign Application Priority Data
Oct. 12, 2005 (JP) 2005-297221

(51) Int. Cl. H01L 21/00; H01L 21/28; H01L 21/31; H01L 21/3205; H01L 21/469

(52) U.S. Cl. 438/105; 438/602; 438/778

(57) ABSTRACT

In a method for manufacturing a compound semiconductor device, a principal surface of a SiC wafer, on which a compound semiconductor device is located, is bonded to a support substrate with an adhesive having a softening point higher than 200° C. A via hole is formed dry etching, including supplying a fluorine-containing etching gas to a rear side of the SiC wafer. Thereafter, the support substrate and the adhesive are removed. Preferably, the adhesive is formed by reacting one material coating the principal surface of the SiC wafer, and another material coating the support substrate.

### FIELD OF THE INVENTION

The present invention relates to a method for manufacturing a compound semiconductor device, which can be suitably used to manufacture high frequency transistors, MMICs (Microwave Monolithic Integrated Circuits), etc. that employ compound semiconductors. More particularly, the invention relates to an improved method for forming a via hole, which greatly enhances the heat dissipation characteristics of the device.

### BACKGROUND ART

A conventional method for manufacturing a compound semiconductor device includes the following sequential steps: forming a via hole by dry etching using a photosensitive polyimide mask; removing the photosensitive polyimide mask; depositing a metal wire extending from within the via hole to the vicinity of the MMIC device on the principal surface of the substrate; covering the principal surface of the substrate with a photosensitive polyimide resin so as to fill the via hole; bonding the principal surface side of the compound semiconductor substrate to a support substrate made of glass, sapphire, etc. by use of a high softening point wax (e.g., proof wax having a softening point of 150° C.), the principal surface side of the substrate having the device formed thereon; and reducing the thickness of the rear surface layer of the compound semiconductor substrate. (See, for example, page 5 and FIG. 1 of Japanese Patent Laid-open No. 2003-7706.)

Conventional techniques such as described above use a low softening point wax and hence have the following disadvantages. For example, assume that a wafer formed of a material preferably requiring a high processing temperature (such as SiC) has been bonded to a support substrate with a wax having a softening point of 100° C. In such a case, when a via hole is formed in the wafer by plasma etching, the maximum allowable stage temperature is approximately 80° C. Therefore, the temperature of the stage must be initially set to as low as 50° C or less, taking into account the temperature rise due to the radiation heat from the plasma. (The stage temperature increases to 80° C during the etching process.) This results in a reduced etching rate and formation of a via hole having a tapered shape if its depth is large. To overcome this problem, it is necessary to reduce the thickness of the wafer to a few tens of microns, for example. However, a reduction in the thickness of the wafer increases the difficulty of handling the wafer.

The present invention has been devised to solve the foregoing problems with the prior art technique. It is, therefore, an object of the present invention to provide a method for manufacturing a compound semiconductor device in such a way that: an increased etching rate can be achieved even for a wafer requiring a high processing temperature, such as a SiC wafer; via holes can be formed to have a rectangular shape in vertical cross section and hence have substantially vertical sidewalls without extremely reducing the thickness of the SiC wafer; and the wafer is easy to handle.

### SUMMARY OF THE INVENTION

According to one aspect of the present invention, in a method for manufacturing a compound semiconductor device, a principal surface side of a Si wafer is bonded to a support substrate with an adhesive having a softening point higher than 200° C., wherein the principal surface side of a Si wafer has a compound semiconductor device formed thereon, and the support substrate is adapted to hold said SiC wafer. Then, a via hole is formed through dry etching by applying a fluorine-containing etching gas to a rear side of said SiC wafer.

According to the present invention, the wafer is bonded to the support substrate with an adhesive having a softening point higher than 200° C. Since the adhesive has such a high softening point, one can assume that it has substantially no softening point, allowing for etching at high temperature. Therefore, it is possible to increase the etching rate and improve the perpendicularity of the sidewalls of the via hole. Further, the improvement in the shape of the via hole will lead to enhanced heat dissipation characteristics of the wafer. Furthermore, the above arrangement reduces the cost for the grinding required to reduce the thickness of the wafer, as well as facilitating handling of the wafer.

Other and further objects, features and advantages of the invention will appear more fully from the following description.

### BRIEF DESCRIPTION OF THE DRAWINGS

FIGS. 1A to 1E show cross-sectional views schematically illustrating a via hole forming process employed by a method for manufacturing a compound semiconductor device according to the present invention.

FIG. 1A shows a SiC wafer bonded to a support substrate.

FIG. 1B shows the SiC wafer with the reduced thickness.

FIG. 1C shows the SiC wafer with a formed via hole.

FIG. 1D shows the SiC wafer after the support substrate has been dissolved and removed.

FIG. 1E shows the SiC wafer after an adhesive has been completely removed.

### DETAILED DESCRIPTION OF THE PREFERRED EMBODIMENT

First Embodiment

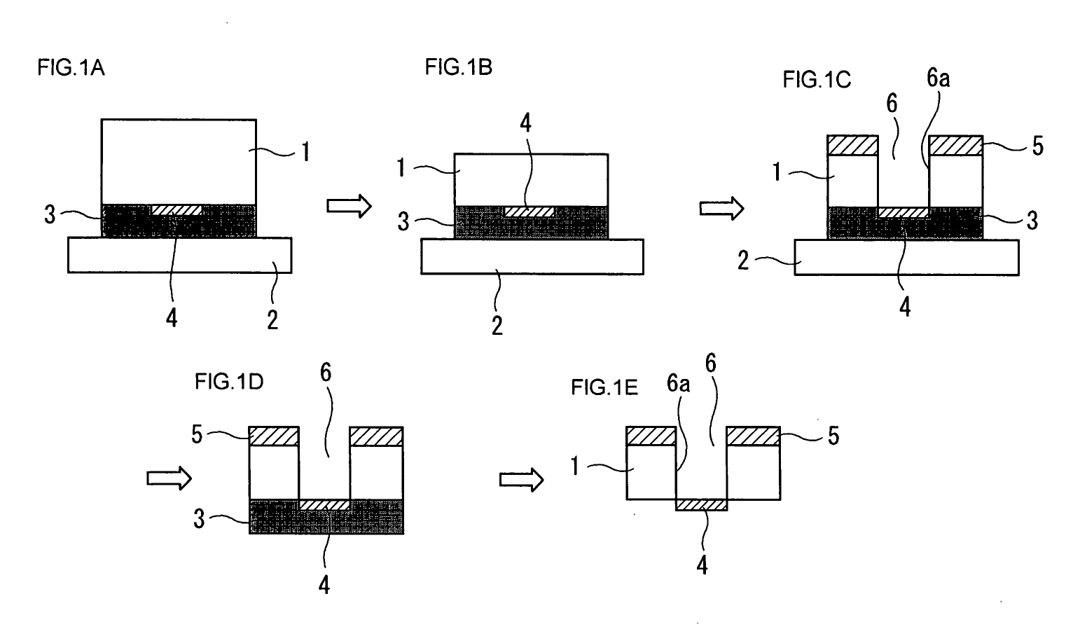

FIGS. 1A to 1E show cross-sectional views schematically illustrating a via hole forming process employed by a method for manufacturing a compound semiconductor device according to a first embodiment of the present invention. Specifically, FIGS. 1A to 1E show the sequential process steps of the via hole forming process. Referring to the figure, reference numeral 1 denotes a SiC wafer formed of single-crystal SiC, i.e., a substrate material for the compound semiconductor device; 2, a support substrate made up of a GaAs wafer and used to hold the SiC wafer 1; 3, an adhesive for bonding the SiC wafer 1 to the support substrate 2; 4, an electrode of gold (Au) deposited on a predetermined region of the principal surface of the SiC wafer 1 (or the undersurface of the SiC wafer 1 in the figures); 5, a Ni layer provided on predetermined regions on the rear side of the SiC wafer 1; 6, a via hole; and 6a, sidewalls of the via hole. It should be noted that according to the present embodiment, the adhesive 3 is formed as result of a reaction between the following two materials: a first material made of a negative resist primarily composed of an acrylic resin and a cross-linking agent (both not shown in the drawings); and a second material made of a wax that is dissolved in a solvent such as toluene and that is primarily composed of a terpene resin and a vinyl acetate resin.

There will now be described the major steps in the method for manufacturing a compound semiconductor device. For example, though not shown in the drawings, a number of multilayered compound semiconductor devices (MMIC) formed of a Group III-V nitride compound semiconductor material such as GaN are formed on the principal surface of a SiC wafer 1 by a known method. Then, an electrode 4 of Au is deposited on a predetermined via hole forming region so as to cover the electrode portion of the compound semiconductor device (not shown). After that, although not shown in the drawings, a first material made of the above negative resist is coated onto the entire principal surface of the SiC wafer 1 to a thickness of approximately 10 μm, and a second material made of the above wax is coated onto a separate support substrate 2 made up of a GaAs wafer to a thickness of approximately 40 μm. Then, as shown in FIG. 1A, the principal surface of the SiC wafer 1 coated with the first material is bonded to the surface of the support substrate 2 coated with the second material.

Then, the SiC wafer 1 with the support substrate 2 thus bonded thereto is placed within a vacuum chamber (not shown) maintained at a pressure of 30 Pa and is pressed under atmospheric pressure by a press attached thereto while its temperature is increased to 145° C. in order to remove bubbles from between the SiC wafer 1 and the support substrate 2. Then, the SiC wafer 1 with the support substrate 2 bonded thereto is heated to 230° C. to cause the first material (a negative resist) and the second material (a wax) to react with each other to form the adhesive 3. FIG. 1(a) shows a cross section of the compound semiconductor wafer in this step. The adhesive 3 thus formed does not soften even at as high as 200° C. and reliably protects the compound semiconductor devices and the electrode 4 formed on the principal surface of the SiC wafer 1 while securely fixing the SiC wafer 1 to the support substrate 2. Furthermore, since the SiC wafer 1 is heated under reduced pressure during the above heating process, the amount of gas escaping from the adhesive 3 during the subsequent plasma etching process is reduced.

Then, the rear surface of the SiC wafer 1 is ground by a known method, for example, by use of diamond abrasive particles, to reduce the thickness of the SiC wafer 1 to 150 μm or less (100-150 μm). FIG. 1B shows the SiC wafer 1 after its thickness has been reduced by the above process. It should be noted that the reason for reducing the thickness of the SiC wafer 1 to 150 μm or less is that when compound semiconductor devices made of a GaN material are formed on a wafer having such a small thickness and energized, the heat generated from these devices substantially does not affect the device characteristics.

Then, a known image reverse resist is coated onto the rear surface of the SiC wafer 1 and patterned by lithography. After that, Ti and Pd are deposited and a lift-off process is carried out. Then, the Ni layer 5 having a predetermined pattern is formed to a thickness of 3-4μm by electroless plating using Pd as a catalyst. Then, a via hole(s) is formed by dry etching using a fluorine-containing etching gas. This process is performed by, for example, a known ECR (Electron Cyclotron Resonance) plasma etching apparatus (not shown) using the Ni layer 5 as a mask. Since the adhesive 3 does not soften even at 200° C., the temperature of the stage during this via hole forming process can be set higher than conventional values, that is, for example, set to 150-180° C.

Specifically, according to the present embodiment, the conditions under which the via hole(s) is formed are such that: the etching gas is SF₆/O₂; the flow rates of the SF₆ gas and the O₂ gas are 190 sccm and 10 sccm, respectively; the pressure within the etching chamber (APC) is 1.5 Pa; the antenna RF (power) and the bias RF (power) are 2000 W and 150 W, respectively; and the stage temperature is 150° C. Each via hole 6 experimentally formed according to the present embodiment had a rectangular shape in vertical cross section and hence had vertical sidewalls 6a as shown in FIG. 1C. It should be noted that since the stage temperature was high in the dry etching process (as described above), the energy supplied from the stage to the SiC wafer 1 exceeded the activation energy of the reaction between the SiC wafer 1 and the fluorine radicals within the plasma, thereby promoting the chemical reaction. Since the radicals promoted isotropic etching, the etching rate was 6.5-7.5 times higher than conventional etching rates.

Then, the GaAs support substrate 2 is dissolved in aqueous tartaric acid and thereby removed. FIG. 1D shows the SiC wafer 1 after the support substrate 2 has been dissolved and thereby removed from the SiC wafer 1 shown in FIG. 1C. Then, the adhesive 3 left on the principal surface of the SiC wafer 1 (that is, the undersurface of the SiC wafer 1 in FIG. 1) is removed by an organic solvent. Specifically, the SiC wafer 1 was actually dipped in a resist stripper composed of phenol and o-dichlorobenzene to remove the adhesive 3. Then, the SiC wafer 1 was dipped in SOLFINE (trade name), predominantly composed of solvent naphtha, and in acetone sequentially to remove the organic residues. After that, the SiC wafer 1 was subjected to steam drying using isopropyl alcohol. FIG. 1E shows the SiC wafer 1 after the adhesive 3 has been completely removed by the above process.

Then, after the Ni layer 5 is removed by a known method, a rear conductor made up of, for example, an Au film is formed to extend from the bottom portion and the sidewalls 6a of the via hole 6 to the rear surface of the SiC wafer 1. Then, inspection, dicing, and assembly processes, etc. are performed to produce a desired compound semiconductor device. Since the compound semiconductor device thus produced employs the SiC wafer 1 as its substrate, it exhibits good heat conduction characteristics and hence good heat dissipation characteristics, which allows the device to operate as a high frequency device. Furthermore, this device can be easily adapted to deliver high power.

According to the first embodiment of the present invention described above, the principal surface side of the SiC wafer 1 is bonded to the support substrate 2 with the adhesive 3 having a softening point higher than 200° C., and then a via hole is formed in the SiC wafer 1 through dry etching by applying a fluorine-containing etching gas to the rear surface side of the SiC wafer 1. Therefore, unlike conventional techniques, one can assume that the adhesive 3 has substantially no softening point, that is, the softening point of the adhesive 3 does not affect the etching process in any way, allowing for etching at high temperature. Further according to the present embodiment, when the adhesive is formed through a reaction, the wafer is heated at a temperature higher than the etching temperature. This prevents gas escape during the subsequent dry etching process.

As a result, it is possible to increase the etching rate and improve the perpendicularity of the sidewalls 6a of the via hole 6. For example, with a wafer having a thickness of 100 μm or more, conventional techniques can form only a tapered via hole having a funnel shape. The present embodiment, on the other hand, allows for formation of a via hole having a rectangular shape, since the wafer can be etched at high temperature. Further, such an improvement in the shape of the via hole will lead to enhanced heat dissipation characteristics. Further, since the via hole has a rectangular shape in vertical cross section, there is no need to reduce the thickness of the wafer substrate 1. This means that the cost of grinding the wafer is reduced and the easy handling of the wafer is maintained. Thus, the present embodiment has various advantageous effects.

Although the present embodiment has been described with reference to the case where the adhesive 3 is formed as a result of a reaction between the first and second materials, the present invention is not limited to this particular arrangement. For example, the adhesive 3 may be formed of a single liquid that can be thermally hardened, or may be formed of a wax having a softening point of approximately 200° C. or higher. Further, it may be of the type that is hardened through a crosslinking reaction by applying ultraviolet light or an electron beam as well as heat. It should be noted that if the softening point of the adhesive 3 is lower than 200° C., the temperature of the stage in the dry etching process must be lowered, resulting in a reduction in the etching rate and formation of a funnel-shaped via hole. Therefore, the softening point of the adhesive is preferably 200° C. or higher.

Further, the first and second materials are not limited to those described above. For example, the second material may be a wax commonly used in the semiconductor industry. That is, any adhesive (or wax) can be used if it meets the follow requirements: has no softening point or has a softening point of approximately 200° C. or higher when the SiC wafer 1 has been adhered to the support substrate 2; has no adverse effect on the SiC wafer 1 under the dry etching conditions; discharges gas only in an amount less than the maximum allowable amount; and can be removed by use of an organic solvent, etc. after the via hole forming process.

Further, although the present embodiment uses a GaAs wafer as the support substrate 2, the present invention is not limited to this particular type of support substrate. The support substrate 2 may be formed of a compound, metal, alloy, or any other material that is soluble in an acid or alkali solution or in an organic solvent and that exhibits sufficient etching resistance when SiC is plasma etched. It should be noted that although the present embodiment uses tartaric acid to dissolve the support substrate 2, the support substrate 2 may be dissolved in any other acid, alkali, or organic solvent, or a mixture thereof, depending on the materials of the support substrate 2.

Further, although the present embodiment employs an ECR plasma etching apparatus, a different type of dry etching apparatus, such as an ICP (Inductively Coupled Plasma) etching apparatus, may be used. Further, suitable examples of etching gases include, in addition to SF₆ described above, fluorine-containing gases used for etching SiC, such as NF3, BF₃, PF₃, CHF₃, and CF₄ and a mixture thereof. It should be noted that these fluorine-containing gases are mixed with, for example, O₂ or Ar when they are used in an etching process.

The stage temperature of the plasma etching apparatus may be set to 50-200° C. (higher than conventional values) during the dry etching process though it is not limited to particular values, since the adhesive 3 has a softening point higher than 200° C and hence one can assume that the adhesive 3 has substantially no softening point. It should be noted that if the stage temperature is reduced, the reaction between the fluorine-containing etching gas and the SiC wafer 1, i.e., the substrate is not promoted, resulting in a reduction in the etching rate and formation of a funnel-shaped via hole. Therefore, the stage temperature is preferably set to 50° C. or higher, more preferably 100° C. or higher, so that the via hole has an appropriate shape and the time required to form the via hole is sufficiently reduced.

Further, although the present embodiment has been described with reference to the case where compound semiconductor devices made of a Group Ill-V nitride compound semiconductor material such as GaN are formed on the surface of the SiC wafer 1, the present invention is not limited to this particular arrangement. It goes without saying that a different type of compound semiconductor material may be used. Further, the present invention is not limited to MMICs. The invention can be applied to any compound semiconductor device. It should be understood that the present invention is not limited to the embodiment described above, and various alterations and modifications may be made thereto without departing from the spirit and scope of the invention.

Obviously many modifications and variations of the present invention are possible in the light of the above teachings. It is therefore to be understood that, within the scope of the appended claims, the invention may by practiced otherwise than as specifically described.

The entire disclosure of a Japanese Patent Application No. 2005-297221, filed on Oct. 12, 2005 including specification, claims, drawings and summary, on which the Convention priority of the present application is based, are incorporated herein by reference in its entirety.

1. A method for manufacturing a compound semiconductor device, comprising:
bonding a principal surface side of SiC wafer to a support substrate with an adhesive having a softening point higher than 200° C, said principal surface side having a compound semiconductor device thereon, said support substrate holding said SiC wafer; and
forming a via hole by dry etching, including supplying a fluorine-containing etching gas to a rear side of said SiC wafer.

2. The method as claimed in claim 1, further comprising, after forming said via hole, removing said support substrate and said adhesive.

3. The method as claimed in claim 1, including forming said adhesive reacting a first material and a second material, said first material coating one of said principal surface side of said SiC wafer and a surface of said support substrate, said second material coating the other of said principal surface side of said SiC wafer and said surface of said support substrate, said reaction occurring when said principal surface side of said SiC wafer is bonded to said surface of said support substrate.

4. The method as claimed in claim 3, wherein:
said first material is a negative resist primarily composed of an acrylic resin and a crosslinking agent; and
said second material is a wax including a terpene resin and a vinyl acetate resin.

5. The method as claimed in claim 1, wherein:
said support substrate exhibits etching resistance during said dry etching of said SiC wafer; and
said support substrate is a material soluble in an acid or alkali solution or in an organic solvent.

6. The method as claimed in claim 1, including forming said via hole by dry etching in an ICP or ECR plasma etching apparatus with the stage temperature set between 50° C. and 200° C.

7. The method as claimed in claim 6, including setting said stage temperature between 100° C. and 200° C.
